(19) United States
(12) Patent Application Publication
(10) Pub. No.: US 2023/0235455 A1
(43) Pub. Date: Jul. 27, 2023

(54) SUBSTRATE TREATMENT APPARATUS

(71) Applicant: JUSUNG ENGINEERING CO., LTD., Gwangju-Si, Gyeonggi-Do (KR)

(72) Inventors: Duck Ho KIM, Gwangju-Si, Gyeonggi-Do (KR); Hyun Ho KOO, Gwangju-Si, Gyeonggi-Do (KR); Chang Su MHA, Gwangju-Si, Gyeonggi-Do (KR); Ae Jung PARK, Gwangju-Si, Gyeonggi-Do (KR); Sang Du LEE, Gwangju-Si, Gyeonggi-Do (KR); Min Seok CHAE, Gwangju-Si, Gyeonggi-Do (KR)

(21) Appl. No.: 18/020,924

(22) PCT Filed: Aug. 6, 2021
(86) PCT No.: PCT/KR2021/010455

§ 371 Date: Feb. 10, 2023

(30) Foreign Application Priority Data
Aug. 25, 2020 (KR) 10-2020-0106991
Jul. 28, 2021 (KR) 10-2021-0099417

(51) Int. Cl. C23C 16/455; C23C 16/448

(52) U.S. Cl. CPC C23C 16/45512; C23C 16/45561; C23C 16/448; H01L 21/02565

(57) ABSTRACT

The present disclosure relates to an apparatus for processing a substrate, and more particularly, to an apparatus for processing a substrate, which deposits a thin-film on a substrate.

The apparatus for processing a substrate in accordance with an exemplary embodiment includes a plurality of source gas supply units configured to respectively supply a plurality of source gases among which at least one contains (3-Dimethylaminopropyl)Dimethylindium (DADI), a gas mixing unit connected to each of the plurality of source gas supply units and having an inner space in which each of the plurality of source gases moves at a passing speed less than a supply speed of each of the plurality of source gases, and a chamber connected with the gas mixing unit and having a reaction space to which the source gases mixed in the inner space are supplied.

### TECHNICAL FIELD

The present disclosure relates to an apparatus for processing a substrate, and more particularly, to an apparatus for processing a substrate, which deposits a metal oxide thin-film on a substrate.

### BACKGROUND ART

Since a metal oxide thin-film, e.g., an organic metal oxide thin-film, has an excellent property of low power and high mobility, the metal oxide thin-film is used as a protection layer, a transparent conductive layer, or a semiconductor layer formed on a substrate in a semiconductor device, a display apparatus, or a solar cell.

The metal oxide thin-film may be made of a zinc (Zn) oxide doped with at least one of indium (In) and gallium (Ga), e.g., an indium zinc oxide (IZO), a gallium zinc oxide (GZO), and an indium gallium zinc oxide (IGZO). The metal oxide thin-film may have various properties according to a composition ratio of indium (In), gallium (Ga), and Zinc (Zn).

Typically, the metal oxide thin-film is deposited on a substrate in a sputtering deposition method by using a target in which indium (In), gallium (Ga), and Zinc (Zn) are mixed with a predetermined composition. However, in this sputtering method, since a composition ratio of the metal oxide thin-film is directly fixed by the composition ratio of the target, the target itself may be replaced to change the composition ratio of the metal oxide thin-film. Also, in case of the sputtering method, a property of the metal oxide thin-film is varied because the composition of the target is unintentionally changed as the number of thin-film deposition increases although an excellent thin-film property is exhibited at the beginning of the sputtering process. Thus, the sputtering process has a disadvantage of frequently replacing the target to cause reduction in productivity and increase in costs.

### RELATED ART DOCUMENT

(Patent document 1) KR10-2009-0117543 A

### DISCLOSURE OF THE INVENTIVE CONCEPT

### Technical Problem

The present disclosure provides an apparatus for processing a substrate, which is capable of depositing a metal oxide thin-film on a substrate by using a chemical vapor deposition method.

The present disclosure also provides an apparatus for processing a substrate, which is capable of easily controlling a composition ratio of a metal oxide thin-film.

### Technical Solution

In accordance with an exemplary embodiment, an apparatus for processing a substrate includes: a plurality of source gas supply units configured to respectively supply a plurality of source gases among which at least one contains (3-Dimethylaminopropyl)Dimethylindium (DADI); a gas mixing unit connected to each of the plurality of source gas supply units and having an inner space in which each of the plurality of source gases moves at a passing speed less than a supply speed of each of the plurality of source gases; and a chamber connected with the gas mixing unit and having a reaction space to which the source gases mixed in the inner space are supplied.

The plurality of source gas supply units may include: a plurality of source storages in which a plurality of source materials for generating the plurality of source gases are respectively stored with a liquid state; and a plurality of source gas pipes configured to form flow paths that respectively connect the plurality of source storages and the gas mixing unit, and the inner space may have a cross-sectional area crossing a direction in which the plurality of source gases pass, which is greater than a sum of cross-sectional areas of the flow paths respectively formed in the plurality of source gas pipes.

The apparatus may further include a mixed gas pipe configured to form a flow path configured to connect the gas mixing unit and the chamber, and the flow path formed in the mixed gas pipe may have a cross-sectional area less than that of the inner space crossing the direction in which the plurality of source gases pass.

The flow path formed in the mixed gas pipe may have a cross-sectional area greater than a sum of cross-sectional areas of the flow paths respectively formed in the plurality of source gas pipes.

The inner space may have a volume greater than a maximum volume of the plurality of source gases supplied per hour from the plurality of source gas supply units.

The plurality of source gas supply units may further include a plurality of carrier gas suppliers configured to supply a carrier gas to each of the plurality of source storages, and the apparatus may further include a control unit configured to adjust a supply amount of each of the carrier gases supplied from the plurality of carrier gas suppliers.

The control unit may adjust the supply amount of each of the carrier gases in proportional to a mixing ratio of the source gases mixed in the inner space.

The plurality of source storages may include: a first source storage configured to store a source material containing (3-Dimethylaminopropyl)Dimethylindium (DADI); a second source storage configured to store a source material containing at least one of trimethylgallium (TMG) and triethylgallium (TEG); and a third source storage configured to store a source material containing at least one of diethylzinc (DEG) and dimethylzinc (DMZ).

The plurality of source gas supply units may further include a plurality of source storage heaters configured to respectively heat the plurality of source storages, and the control unit may control the plurality of source storage heaters so that the plurality of source storages are maintained at different temperatures.

The apparatus may further include a mixed gas pipe heater configured to heat the mixed gas pipe, and the control unit may control the mixed gas pipe heater so that the mixed gas pipe is maintained at a temperature in a range from 30° C. to 150° C.

### Advantageous Effects

In accordance with an exemplary embodiment, the plurality of source gases for depositing the oxide thin-film may be mixed and uniformly supplied onto the substrate.

Also, a composition of the oxide thin-film deposited on the substrate may be easily changed according to preferred characteristics.

Although the specific embodiments are described and illustrated by using specific terms, the terms are merely examples for clearly explaining the embodiments, and thus, it is obvious to those skilled in the art that the embodiments and technical terms can be carried out in other specific forms and changes without changing the technical idea or essential features. Therefore, it should be understood that simple modifications according to the embodiments of the present invention may belong to the technical spirit of the present invention.

### BRIEF DESCRIPTION OF THE DRAWINGS

FIG. 1 is a schematic view illustrating an apparatus for processing a substrate in accordance with an exemplary embodiment;

FIG. 2 is a view illustrating a state in which a source gas moves through a gas mixing unit in accordance with an exemplary embodiment;

FIG. 3 is a view illustrating a state of viewing the gas mixing unit in one direction in accordance with an exemplary embodiment; and

FIG. 4 is a view illustrating a state in which plasma is formed in a reaction space accordance with an exemplary embodiment.

### DETAILED DESCRIPTION

Hereinafter, exemplary embodiments of the present invention will be described in detail with reference to the accompanying drawings. The present invention may, however, be embodied in different forms and should not be construed as limited to the embodiments set forth herein. Rather, these embodiments are provided so that the present invention will be thorough and complete, and will fully convey the scope of the present invention to those skilled in the art. In the drawings, the thicknesses of layers and regions are exaggerated for clarity. In the figures, like reference numerals refer to like elements throughout.

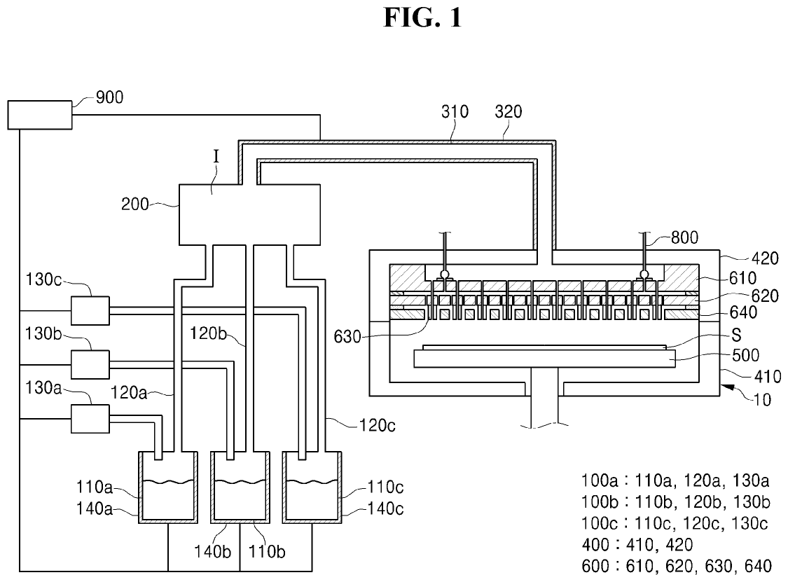

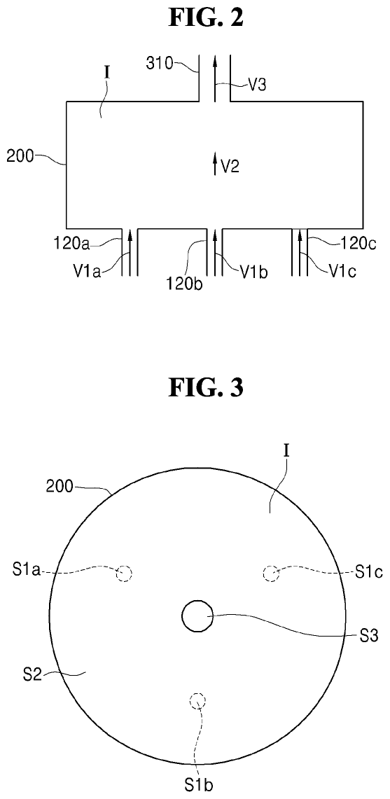

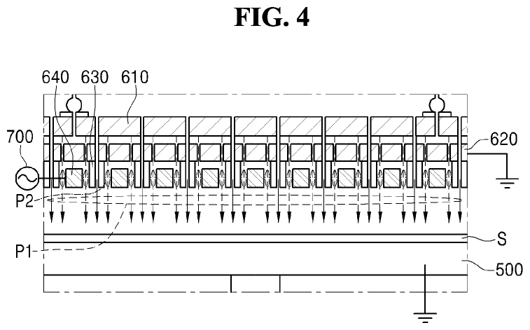

FIG. 1 is a schematic view illustrating an apparatus for processing a substrate in accordance with an exemplary embodiment. Also, FIG. 2 is a view illustrating a state in which a source material gas moves through a gas mixing unit in accordance with an exemplary embodiment, and FIG. 3 is a view illustrating a state of viewing the gas mixing unit in one direction in accordance with an exemplary embodiment.

Referring to FIGS. 1 to 3, an apparatus for processing a substrate (hereinafter, referred to as a substrate processing apparatus) in accordance with an exemplary embodiment includes: a plurality of source gas supply units 100a, 100b, and 100c for respectively supplying a plurality of source gases of which at least one contains (3-Dimethylaminopropyl)Dimethylindium (DADI); a gas mixing unit 200 connected with each of the plurality of source gas supply units 100a, 100b, and 100c and having an inner space I to have a passing speed slower than a supply speed by which the plurality of source gases are supplied; and a chamber 400 connected with the gas mixing unit 200 and having a reaction space to which a source gas mixed in the inner space I is supplied.

The substrate processing apparatus in accordance with an exemplary embodiment may perform a thin-film deposition process that deposits a thin-film on a substrate S by supplying a source gas and a reactant gas. Here, the thin-film deposition process may deposit a zinc (Zn) oxide doped with at least one of indium (In) and gallium (Ga), e.g., a metal oxide thin-film such as an indium zinc oxide (IZO), a gallium zinc oxide (GZO), and an indium gallium zinc oxide (IGZO), on the substrate S. Hereinafter, although a substrate processing apparatus for depositing an IGZO metal oxide thin-film on the substrate S is exemplarily described, an exemplary embodiment may be applied to a process of depositing various metal oxide thin-films on the substrate S.

The source gas supply unit is provided in plurality, and the plurality of source gas supply units 100a, 100b, and 100c respectively supply a plurality of source gases for depositing a thin-film. At least one of the plurality of source gas supply units 100a, 100b, and 100c for depositing the IGZO metal oxide thin-film on the substrate S may be a first source gas supply unit 100a for supplying a source gas containing (3-Dimethylaminopropyl)Dimethylindium (DADI) as illustrated in FIG. 1. The source gas containing the DADI is supplied to provide an indium (In) gas. The plurality of source gas supply units 100a, 100b, and 100c may further include a second source gas supply unit 100b for supplying a gallium (Ga) gas and a third source gas supply unit 100c for supplying a zinc (Zn) gas.

The plurality of source gas supply units 100a, 100b, and 100c may include a plurality of source storages 110a, 110b, and 110c in which a plurality of source materials for generating the plurality of source gases are respectively stored and a plurality of source gas pipes 120a, 120b, and 120c forming flow paths respectively connecting the plurality of source storages 110a, 110b, and 110c to the gas mixing unit 200. When the plurality of source gas supply units 100a, 100b, and 100c includes the first source gas supply unit 100a, the second source gas supply unit 100b, and the third source gas supply unit 100c, the first source gas supply unit 100a may include a first source storage 110a and a first source gas pipe 120a, the second source gas supply unit 100b may include a second source storage 110b and a second source gas pipe 120b, and the third source gas supply unit 100c may include a third source storage 110c and a third source gas pipe 120c.

Each of the source storages may have a container shape having an inner storage space, and a source material for generating a source gas may be stored in the storage space. Here, a first source material for generating an indium (In) gas may be stored in the first source storage 110a, and the first source material may contain the DADI. Also, a second source material for generating a gallium (Ga) gas may be stored in the second source storage 110b, and the second source material may contain at least one of trimethylgallium (TMG) and triethylgallium (TEG). Also, a third source material for generating a zinc (Zn) gas may be stored in the third source storage 110c, and the third source material may contain at least one of diethylzinc (DEZ) and dimethylzinc (DMZ). Here, the first source material, the second source material, and the third source material, each of which is in a liquid state, may be stored in the first source storage 110a, the second source storage 110b, and the third source storage 110c, respectively.

Here, the plurality of source gas supply units may further include a plurality of source storage heaters 140a, 140b, and 140c for respectively heating the plurality of source storages 110a, 110b, and 110c. That is, the first source gas supply unit 100a may include a first source storage heater 140a for heating the first source storage 110a, the second source gas supply unit 100b may include a second source storage heater 140b for heating the second source storage 110b, and the third source gas supply unit 100c may include a third source storage heater 140c for heating the third source storage 110c. The first source storage heater 140a, the second source storage heater 140b, and the third source storage heater 140c may respectively heat the first source storage 110a, the second source storage 110b, and the third source storage 110c, and, through this, the first source material, the second source material, and the third source material, each of which is in the liquid state, may be vaporized. Here, each of the plurality of source storage heaters 140a, 140b, and 140c may have a heating jacket shape surrounding each of the first source storage 110a, the second source storage 110b, and the third source storage 110c.

Also, the plurality of source gas supply units 100a, 100b, and 100c may further include a plurality of carrier gas suppliers 130a, 130b, and 130c for respectively supplying a carrier gas to the plurality of source storages. That is, the first source gas supply unit 100a may include a first carrier gas supplier 130a for supplying the carrier gas to the first source storage 110a, the second source gas supply unit 100b may include a second carrier gas supplier 130b for supplying the carrier gas to the second source storage 110b, and the third source gas supply unit 100c may include a third carrier gas supplier 130c for supplying the carrier gas to the third source storage 110c. The first carrier gas supplier 130a, the second carrier gas supplier 130b, and the third carrier gas supplier 130c may respectively supply the carrier gas to the first source storage 110a, the second source storage 110b, and the third source storage 110c, and accordingly, each of the first source gas, the second source gas, and the third source gas, which are obtained by vaporizing the source materials, may be supplied to the gas mixing unit 200. Here, at least one of non-reactive gases, e.g., an argon (Ar) gas, a hydrogen (H₂) gas, a nitrogen (H₂) gas, and a helium (He) gas, may be used as the carrier gas.

The plurality of source gas pipes 120a, 120b, and 120c form flow paths for respectively connecting the plurality of source storages 110a, 110b, and 110c to the gas mixing unit 200. The plurality of source gas pipes 120a, 120b, and 120c may include a first source gas pipe 120a connecting the first source storage 110a and the gas mixing unit 200, a second source gas pipe 120b connecting the second source storage 110b and the gas mixing unit 200, and a third source gas pipe 120c connecting the third source storage 110c and the gas mixing unit 200. Here, each of the first source gas pipe 120a, the second source gas pipe 120b, and the third source gas pipe 120c may have a pipe shape in which a flow path is formed. Also, one end and the other end of the first source gas pipe 120a may be connected to the first source storage 110a and the gas mixing unit 200, respectively, one end and the other end of the second source gas pipe 120b may be connected to the second source storage 110b and the gas mixing unit 200, respectively, and one end and the other end of the third source gas pipe 120a may be connected to the third source storage 110c and the gas mixing unit 200, respectively. Although not shown, at least one valve may be installed on each of the source gas pipes.

Each of the plurality of source gas supply units 100a, 100b, and 100c may be connected to the gas mixing unit 200, and the inner space I may be defined in the gas mixing unit 200 to have a passing speed less than a supply speed at which each of the plurality of source gases is supplied. The gas mixing unit 200 may include a mixer.

The gas mixing unit 200 may have a container shape having the inner space I, and each of the first source gas pipe 120a, the second source gas pipe 120b, and the third source gas pipe 120c may be communicated with the inner space I. Here, the first source gas, the second source gas, and the third source gas, which are supplied to the gas mixing unit 200 through the first source gas pipe 120a, the second source gas pipe 120b, and the third source gas pipe 120c, respectively, are mixed while passing through the inner space I, and the mixed source gas is provided to the chamber 400 connected with the gas mixing unit 200.

Here, as illustrated in FIG. 2, when a speed at which the first source gas moves in the first source gas pipe 120a toward the gas mixing unit 200 is referred to as a first supply speed V1a, a speed at which the second source gas moves in the second source gas pipe 120b toward the gas mixing unit 200 is referred to as a second supply speed V1b, and a speed at which the third source gas moves in the third source gas pipe 120c toward the gas mixing unit 200 is referred to as a third supply speed V1c, the inner space I of the gas mixing unit 200 may allow the plurality of source gases to pass through the inner space I at a passing speed V2 that is slower than each of the first supply speed V1a, the second supply speed V1b, and the third supply speed V1c. That is, the inner space I of the gas mixing unit 200 may have a shape allowing the plurality of source gases to pass the inner space I at the passing speed V2 slower than the slowest supply speed among the first supply speed V1a, the second supply speed V1b, and the third supply speed V1c. In this case, movement speeds at which the first source gas, the second source gas, and the third source gas are supplied to the inner space I may decrease, and accordingly, the first source gas, the second source gas, and the third source gas may secure a sufficient time for being uniformly mixed in the inner space I before being discharged from the gas mixing unit 200.

To this end, as illustrated in FIG. 3, the inner space I defined in the gas mixing unit 200 may have a cross-sectional area S2 greater than a sum of cross-sectional areas S1a, S1b, and S2c of flow paths respectively defined in the plurality of source gas pipes 120a, 120b, and 120c. Here, the cross-sectional area S2 crossing a direction in which the plurality of source gases pass represents the cross-sectional area S2 of the inner space I when the inner space I is cut by a plane crossing all of a path through which the first source gas passes the inner space I, a path through which the second source gas passes the inner space I, and a path through which the third source gas passes the inner space I. As described above, a portion in which the cross-sectional area S2 is greater than the sum of the cross-sectional areas S1a, S1b, and S1c may be at least a portion of the inner space I.

Here, when the cross-sectional area S2 crossing the direction in which the plurality of source gases pass is greater than the sum of the cross-sectional areas S1a, S1b, and S1c of the flow paths respectively defined in the plurality of source gas pipes, each of the first source gas, the second source gas, and the third source gas may generally pass at the passing speed V2 slower than each of the first supply speed V1a, the second supply speed V1b, and the third supply speed V1c. Even in the above-described case, however, when the inner space I has an insufficient volume, the passing speed V2 at which the first source gas, the second source gas, and the third source gas pass the inner space I may not decrease. Thus, the inner space I may have a volume greater than a maximum volume of the plurality of source gases supplied per hour from the plurality of source gas supply units 100a, 100b, and 100c. That is, the inner space I defined in the gas mixing unit 200 may have a volume greater than a sum of a maximum volume of the first source gas supplied per hour from the first source gas supply unit 100a, a maximum volume of the second source gas supplied per hour from the second source gas supply unit 100b, and a maximum volume of the third source gas supplied per hour from the third source gas supply unit 100c. As a result, even when each of the first source gas, the second source gas, and the third source gas supplied to the inner space I has any supply speed, the passing speed V2 may be slower than each supply speed in the inner space I.

The substrate processing apparatus in accordance with an exemplary embodiment may further include a mixed gas pipe 310 that forms a flow path connecting the gas mixing unit 200 and the chamber 400. As described above, the first source gas, the second source gas, and the third source gas are mixed in the inner space I of the gas mixing unit 200, and the mixed source gas is provided to a reaction space of the chamber 400 disposed at the outside of the gas mixing unit 200. Here, the mixed gas pipe 310 has a pipe shape in which a flow path connecting the gas mixing unit 200 and the chamber 400 is formed. Here, the number of the mixed gas pipes 310 may be less than that of the source gas supply units. For example, one the mixed gas pipe may be provided as illustrated.

Here, the flow path defined in the mixed gas pipe 310 may have a cross-sectional area S3 less than the cross-sectional area S2 of the inner space I, which crosses the direction in which the plurality of source gases pass. When the first source gas, the second source gas, and the third source gas are sufficiently mixed in the gas mixing unit 200, the mixed source gas is required to be supplied to the reaction space of the chamber 400 at a speed V3 faster than the passing speed V2. Thus, the flow path defined in the mixed gas pipe 310 may have the cross-sectional area S3 less than the cross-sectional area S2 of the inner space I, which crosses the direction in which the plurality of source gases pass.

Also, the flow path defined in the mixed gas pipe 310 may have the cross-sectional area S3 greater than the sum of cross-sectional areas S1a, S1b, and S2c of flow paths respectively defined in the plurality of source gas pipes 120a, 120b, and 120c. As described above, the first source gas, the second source gas, and the third source gas respectively move the first source gas pipe 120a, the second source gas pipe 120b, and the third source gas pipe 120c at the first supply speed V1a, the second supply speed V1b, and the third supply speed V1c. Here, as the flow path defined in the mixed gas pipe 310 has the cross-sectional area S3 greater than the sum of cross-sectional areas S1a, S1b, and S2c of flow paths respectively defined in the plurality of source gas pipes, the movement speeds V1, V2, and V3 of the first source gas, the second source gas, and the third source gas in the first source gas pipe 120a, the second source gas pipe 120b, and the third source gas pipe 120c are not limited by the movement speed V3 of the mixed source gas. Although not shown, at least one valve may be installed on the mixed gas pipe 310.

The substrate processing apparatus in accordance with an exemplary embodiment may further include a control unit 900 for controlling each of the plurality of source gas supply units 100a, 100b, and 100c. Here, the control unit 900 may adjust a supply amount of the carrier gas supplied from each of the plurality of carrier gas suppliers 130a, 130b, and 130c. When the supply amount of the carrier gas supplied to the first source storage 110a increases, the supply amount of the first source gas supplied to the gas mixing unit 200 increases, and when the supply amount of the carrier gas supplied to the first source storage 110a decreases, the supply amount of the first source gas supplied to the gas mixing unit 200 decreases. This is also true for the second source gas and the third source gas. Thus, the control unit 900 may adjust the supply amount of the first source gas, the second source gas, and the third source gas supplied to the gas mixing unit 200 by adjusting each of supply amounts of the carrier gases supplied from the first carrier gas supplier 130a, the second carrier gas supplier 130b, and the third carrier gas supplier 130c. Accordingly, the source gases mixed in the gas mixing unit 200 may be mixed with various mixing ratios, and the metal oxide thin-film having the various compositions may be deposited on the substrate.

Also, the control unit 900 may control the plurality of source storage heaters 140a, 140b, and 140c so that the plurality of source storages 110a, 110b, and 110c are maintained at different temperatures. As described above, the first source material may include a source material for generating the indium (In) gas, the second source material may include a source material for generating the gallium (Ga) gas, and the third source material may include a source material for generating the zinc (Zn) gas. As described above, since the first source material, the second source material, and the third source material are different materials and have different steam pressures, temperatures for vaporizing the first, second, and third source materials are different. Thus, the control unit 900 may control the plurality of source storage heaters 140a, 140b, and 140c to maintain the first source storage 110a, the second source storage 110b, and the third source storage 110c at different temperatures for vaporizing respective materials. Here, the control unit 900 may control the plurality of source storage heaters 140a, 140b, and 140c to maintain the first source storage 110a, the second source storage 110b, and the third source storage 110c at different temperatures within a range from 25° C. to 150° C.

Although not shown, the plurality of source gas pipes 120a, 120b, and 120c, the gas mixing unit 200, and the mixed gas pipe 310 may be heated by a heater provided separately from the plurality of source storage heaters 140a, 140b, and 140c. That is, the plurality of source gas pipes 120a, 120b, and 120c may be heated by a plurality of source gas pipe heaters (not shown), the gas mixing unit 200 may be heated by a gas mixing unit heater (not shown), and the mixed gas pipe 310 may be heated by a mixed gas pipe heater 320. This is for preventing particles from being generated from each of the source gases or the mixed gas in the plurality of source gas pipes 120a, 120b, and 120c, the gas mixing unit 200, and the mixed gas pipe 310. As described above, when the plurality of source gas pipes 120a, 120b, and 120c, the gas mixing unit 200, and the mixed gas pipe 310 are heated, the control unit 900 may control the plurality of source gas pipe heater (not shown), the gas mixing unit heater (not shown), and the mixed gas pipe heater 320 so that each of the plurality of source gas pipes 120a, 120b, and 120c, the gas mixing unit 200, and the mixed gas pipe 310 maintains a temperature with a range from 30° C. to 150° C. to prevent particle generation. When each of the plurality of source gas pipes 120a, 120b, and 120c, the gas mixing unit 200, and the mixed gas pipe 310 has a temperature less than 30° C., particles may be generated in the pipes, and when the temperature is greater than 150° C., the pipes may be damaged or broken.

The chamber 400 has the reaction space connected with the gas mixing unit 200 and receiving the source gas mixed in the inner space I of the gas mixing unit 200 through the mixed gas pipe 310. That is, the chamber 400 provides a predetermined reaction space and maintains sealing of the reaction space. The chamber 400 may include a body 410 including a flat part having an approximately circular or rectangular shape and a sidewall part extending upward from the flat part to have the predetermined reaction space and a cover 420 having an approximately circular or rectangular shape and disposed on the body 410 to maintain the sealing of the reaction space. However, the chamber 400 is not limited thereto. For example, the chamber 100 may have various shapes corresponding to a shape of the substrate S.

Also, the substrate processing apparatus in accordance with an exemplary embodiment may further include a substrate support unit 500 disposed in the chamber and supporting the substrate S provided in the chamber 400, a gas injection unit 600 disposed in the chamber 400 to face the substrate support unit 500 and injecting a process gas toward the substrate support unit 500, and a RF power unit 700 for applying a power to generate plasma in the chamber 400.

The substrate S, which is loaded into the chamber 400 for a thin film forming process, may be seated on the substrate support unit 500. The substrate support unit 500 may include, e.g., an electrostatic chuck to absorb and maintain the substrate S by an electrostatic force so that the substrate S is seated and supported or substrate support capable of supporting the substrate S by vacuum absorption or a mechanical force.

The gas injection unit 600 is installed in the chamber 400, e.g., installed on a bottom surface of the cover 420, and a source gas supply path for supplying the mixed source gas and a reaction gas supply path for supplying the reaction gas are formed in the gas injection unit 600. Here, the above-described mixed gas pipe 310 may be connected to the source gas supply path, and the reaction gas pipe 800 for supplying the reaction gas containing, e.g., oxygen, may be connected to the reaction gas supply path. Here, the source gas supply path and the reaction gas supply path may be independently separated to separately supply the mixed source gas and the reaction gas onto the substrate S so that the mixed source gas and the reaction gas are not mixed.

The gas injection unit 600 may include an upper frame 610 and a lower frame 620. Here, the upper frame 610 is detachably coupled to the bottom surface of the cover 420, and at the same time, a portion of a top surface, e.g., a central portion of the top surface, of the upper frame 610 is spaced a predetermined distance from the bottom surface of the cover 420. Thus, the source gas may be diffused in a space between the top surface of the upper frame 610 and the bottom surface of the cover 420. Also, the lower frame 620 is spaced a predetermined distance from a bottom surface of the upper frame 610. Thus, the reaction gas may be diffused in a space between a top surface of the lower frame 620 and a bottom surface of the upper frame 610. The upper frame 610 and the lower frame 620 may be connected along outer circumference surfaces thereof and form a spaced space therein, thereby being integrated with each other. Alternatively, the outer circumference surfaces of the upper frame 610 and the lower frame 620 may be sealed by a separate sealing member.

The source gas supply path may be formed so that the source gas supplied from the mixed gas pipe 310 is diffused in the space between the bottom surface of the cover 420 and the upper frame 610 and supplied into the chamber 400 by passing through the upper frame 610 and the lower frame 620. Also, the reaction gas supply path may be formed so that the reaction gas supplied from the reaction gas pipe 800 is diffused in the space between the bottom surface of the upper frame 610 and the top surface of the lower frame 620 and supplied into the chamber 400 by passing through the lower frame 620. The source gas supply path and the reaction gas supply path may not be communicated with each other, and accordingly, the source gas and the reaction gas may be separately supplied respectively from the mixed gas pipe 310 and the reaction gas pipe 800 into the chamber 400 through the gas injection unit 600.

A first electrode 630 may be installed on the bottom surface of the lower frame 620, and a second electrode 640 may be spaced a predetermined distance from a lower side of the lower frame 620 and an outer side of the first electrode 630. Here, the lower frame 620 and the second electrode 640 may be connected along outer circumferential surfaces thereof. Alternately, the outer circumferential surfaces of the lower frame 620 and the second electrode 640 may be sealed by a separate sealing member.

As described above, when the first electrode 630 and the second electrode 640 are installed, the source gas may be injected onto the substrate S through the first electrode 630, and the reaction gas may be injected onto the substrate S through a spaced space between the first electrode 630 and the second electrode 640.

A RF power may be applied from the RF power unit 700 to one of the lower frame 620 and the second electrode 640. FIG. 4 is a view illustrating a state in which plasma is formed in the reaction space in accordance with an exemplary embodiment. FIG. 4 illustrates a structure in which the lower frame 620 is grounded, and the RF power is applied to the second electrode 640. When the lower frame 620 is grounded, the first electrode 630 installed on the bottom surface of the lower frame 620 is also grounded. Thus, when the RF power is applied to the second electrode 640, a first activation region, i.e., a first plasma region P1, may be formed between the gas injection unit 600 and the substrate support unit 500, and a second activation region, i.e., a second plasma region P2, may be formed between the first electrode 630 and the second electrode 640.

As illustrated in FIG. 4, the mixed source gas may be supplied into the chamber 400 along an arrow illustrated by a solid line, and the reaction gas may be supplied into the chamber 400 along an arrow illustrated by a dotted line. The mixed source gas may pass through the inside of the first electrode 630 and be supplied into the chamber 400, and the reaction gas may pass through the spaced space between the first electrode 630 and the second electrode 640 and be supplied into the chamber 400.

When the first electrode 630 and the substrate support unit 500 are grounded, and the power is applied to the second electrode 640, the first activation region, i.e., the first plasma region P1, may be formed between the gas injection unit 600 and the substrate support unit 500, and the second activation region, i.e., the second plasma region P2, may be formed between the first electrode 630 and the second electrode 640.

Thus, when the mixed source gas is supplied through the first electrode 630, the mixed source gas is activated in the first plasma region P1 formed outside the gas injection unit 600. Also, when the reaction gas is supplied through the spaced space between the first electrode 630 and the second electrode 640, the reaction gas may be activated in a region between the first electrode 630 and the second electrode 640, which corresponds to the inside of the gas injection unit 600, i.e., a region from the second plasma region P2 to the first plasma region P1. Thus, the substrate processing apparatus in accordance with an exemplary embodiment may respectively activate the mixed source gas and the reaction gas in plasma regions having different sizes. Also, as the mixed source gas and the reaction gas are activated in the plasma regions having different sizes, each of the gases may be distributed through an optimized supply path for depositing the metal oxide thin-film.

Hereinafter, the substrate processing method in accordance with an exemplary embodiment will be described in detail. The substrate processing method in accordance with an exemplary embodiment is performed by using the above-described substrate processing apparatus, and thus features overlapping the above-described features related to the substrate processing apparatus will be omitted.

Firstly, a reaction space of a chamber 400 is formed as a low pressure atmosphere in order to deposit a thin-film on a substrate S.

Thereafter, a source gas injecting process of injecting a mixed source gas onto the substrate S to allow an organic material precursor contained in the mixed source gas to be absorbed onto the substrate S is performed.

The source gas injecting process heats and vaporizes a first source material, a second source material, and a third source material, which are respectively stored with a liquid state in a first source storage 110a, a second source storage 110b, and a third source storage 110c and then supplies a carrier gas to each of the first source storage 110a, the second source storage 110b, and the third source storage 110c, thereby supplying the first source material, the second source material, and the third source material to a gas mixing unit 200.

Here, the first source material, the second source material, and the third source material supplied to the gas mixing unit 200 may have a reduced speed of passing an inner space I of the gas mixing unit 200 to be less than a supply speed through a source gas pipe, and thus the first source material, the second source material, and the third source material may be uniformly mixed in the inner space I of the gas mixing unit 200. The mixed source gas is supplied to a gas injection unit 600 in the chamber 400 through a mixed gas pipe 310.

Thereafter, the mixed source gas supplied to the gas injection unit 600 is blocked, and a purge gas is injected onto the substrate S to purge the organic material precursor remained on the substrate S instead of being absorbed.

Thereafter, a reaction gas injecting process of blocking the purge gas supplied to the gas injection unit 600 of the chamber 400, and injecting a reaction gas and simultaneously generating plasma so that the organic material precursor absorbed to the substrate S reacts with the reaction gas is performed.

The reaction gas injected onto the substrate S is activated by the plasma, and the activated reaction gas reacts with the organic material precursor absorbed to the substrate. Accordingly, an oxide thin-film having a binary system or ternary system may be formed on the substrate.

Thereafter, a reaction gas purge process of blocking the reaction gas supplied to the gas injection unit 600 of the chamber 400 and simultaneously injecting a purge gas onto the substrate S to purge (or remove) a non-reacted gas existing in the reaction space of the chamber is performed. The mixed source gas injecting process, the source gas purge process, the reaction gas injecting process, and the reaction gas purge process form one cycle, and the oxide thin-film is deposited on the substrate S by repeating, a plurality of times, the cycle including the mixed source gas injecting process, the source gas purge process, the reaction gas injecting process, and the reaction gas purge process.

As described above, in accordance with an exemplary embodiment, the plurality of source gases for depositing the oxide thin-film may be mixed and uniformly supplied onto the substrate. Also, a composition of the oxide thin-film deposited on the substrate may be easily changed according to preferred characteristics.

As described above, in accordance with an exemplary embodiment, the plurality of source gases for depositing the oxide thin-film may be mixed and uniformly supplied onto the substrate.

Also, a composition of the oxide thin-film deposited on the substrate may be easily changed according to preferred characteristics.

Although the specific embodiments are described and illustrated by using specific terms, the terms are merely examples for clearly explaining the embodiments, and thus, it is obvious to those skilled in the art that the embodiments and technical terms can be carried out in other specific forms and changes without changing the technical idea or essential features. Therefore, it should be understood that simple modifications according to the embodiments of the present invention may belong to the technical spirit of the present invention.

What is claimed is:

1. An apparatus for processing a substrate, comprising:
a plurality of source gas supply units configured to respectively supply a plurality of source gases among which at least one contains (3-Dimethylaminopropyl)Dimethylindium (DADI);
a gas mixing unit connected to each of the plurality of source gas supply units and having an inner space in which each of the plurality of source gases moves at a passing speed less than a supply speed of each of the plurality of source gases; and
a chamber connected with the gas mixing unit and having a reaction space to which the source gases mixed in the inner space are supplied.

2. The apparatus of claim 1, wherein the plurality of source gas supply units comprise:
a plurality of source storages in which a plurality of source materials for generating the plurality of source gases are respectively stored with a liquid state; and
a plurality of source gas pipes configured to form flow paths that respectively connect the plurality of source storages and the gas mixing unit,
wherein the inner space has a cross-sectional area crossing a direction in which the plurality of source gases pass, which is greater than a sum of cross-sectional areas of the flow paths respectively formed in the plurality of source gas pipes.

3. The apparatus of claim 2, further comprising a mixed gas pipe configured to form a flow path configured to connect the gas mixing unit and the chamber,
wherein the flow path formed in the mixed gas pipe has a cross-sectional area less than that of the inner space crossing the direction in which the plurality of source gases pass.

4. The apparatus of claim 3, wherein the flow path formed in the mixed gas pipe has a cross-sectional area greater than a sum of cross-sectional areas of the flow paths respectively formed in the plurality of source gas pipes.

5. The apparatus of claim 1, wherein the inner space has a volume greater than a maximum volume of the plurality of source gases supplied per hour from the plurality of source gas supply units.

6. The apparatus of claim 3, wherein the plurality of source gas supply units further comprise a plurality of carrier gas suppliers configured to supply a carrier gas to each of the plurality of source storages, and
the apparatus further comprises a control unit configured to adjust a supply amount of each of the carrier gases supplied from the plurality of carrier gas suppliers.

7. The apparatus of claim 6 wherein the control unit adjusts the supply amount of each of the carrier gases in proportional to a mixing ratio of the source gases mixed in the inner space.

8. The apparatus of claim 2, wherein the plurality of source storages comprise:
a first source storage configured to store one of the source materials containing (3-Dimethylaminopropyl)Dimethylindium (DADI);
a second source storage configured to store a source material containing at least one of trimethylgallium (TMG) and triethylgallium (TEG); and
a third source storage configured to store a source material containing at least one of diethylzinc (DEG) and dimethylzinc (DMZ).

9. The apparatus of claim 6, wherein the plurality of source gas supply units further comprise a plurality of source storage heaters configured to respectively heat the plurality of source storages, and
the control unit controls the plurality of source storage heaters so that the plurality of source storages are maintained at different temperatures.

10. The apparatus of claim 6, further comprising a mixed gas pipe heater configured to heat the mixed gas pipe,
wherein the control unit controls the mixed gas pipe heater so that the mixed gas pipe is maintained at a temperature in a range from 30° C. to 150° C.
